(19) United States
(12) Patent Application Publication
(10) Pub. No.: US 2008/0295886 A1
(43) Pub. Date: Dec. 4, 2008

(54) ZNO WHISKER FILMS AND METHOD OF MANUFACTURING SAME

(75) Inventors: Xiulan HU, Aichi (JP); Yoshitake Masuda, Aichi (JP); Kazumi Kato, Aichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: National Institute of Adv. Industrial Sci. and Tech, Chiyoda-ku (JP)

(21) Appl. No.: 12/129,099

(22) Filed: May 29, 2008

(30) Foreign Application Priority Data
May 31, 2007 (JP) 2007-146232

(51) Int. Cl. H01L 31/00; B32B 3/30; B05D 5/00; B01J 19/00

(52) U.S. Cl. 136/256; 428/95; 427/283; 422/68.1; 422/83

(57) ABSTRACT

The present invention is a ZnO whisker film, a manufacturing method thereof and an electronic device material composed of such a ZnO whisker film, the film is composed of primarily (at least 50 mol %) of ZnO crystals, and of accumulated whisker-like particles having an aspect ratio of 2 or more, and the film has a nanostructure with both a high specific surface area and a high electrical conductivity, the film can be manufactured by adjusting one or more solution condition selected from starting material concentration, temperature and pH so as to induce the deposition of ZnO crystals, in a reaction solution system for depositing zinc oxide, and forming thereby a ZnO whisker film on a substrate.

### BACKGROUND OF THE INVENTION

1. Field of the Invention

The present invention relates to a ZnO whisker film and to a method of manufacturing such film. More particularly, the invention relates to a film which is composed primarily (at least 50 mol %) of ZnO crystals and is formed by the accumulation of whisker-like particles having an aspect ratio of 2 or more, and to a method of manufacturing such film. As used herein, the term ‘whisker-like particles’ refers to anisotropic particles which have an aspect ratio of 2 or more and are shaped as whiskers, needles, bars or rods. The ‘aspect ratio’ of a particle refers herein to the length-to-diameter (length/diameter) ratio of the particle. The aspect ratio of spherical particles and cubic particles is 1, whereas the aspect ratio of particles in the shape of needles, bars or whiskers is 1 or more. The present invention provides a ZnO whisker film that is useful as an electronic device for molecular sensors, gas sensors, solution sensors, dye-sensitized solar cells, or the like.

2. Description of the Related Art

Although zinc oxide (ZnO) has been widely used to date in a variety of fields, recently there has been a rise in the use of zinc oxide particularly in dye-sensitized solar cells and molecular sensors, and a growing interest in such characteristics of zinc oxide as its fluorescence properties, its transparency and electrical conductivity. Also, the synthesis of ZnO crystals by solution processes is being actively promoted as a manufacturing method of ZnO crystals, both in keeping with the shift in manufacturing toward processes having a lower environmental impact and to achieve a higher shape controllability. The synthesis of hexagonal prism-like particles of ZnO, ellipsoidal particles of ZnO, and multi-needle particles of ZnO has hitherto been reported (Y. Masuda, N. Kinoshita, F. Sato and K. Koumoto: Crystal Growth & Design 6, 75, (2006)).

The inventors have previously described ZnO whiskers, ZnO whisker films, and methods of manufacturing such whiskers and films (see Unpublished Japanese Patent Application No. 2007-072248); zinc oxide particles, zinc oxide particle films, and methods of manufacturing the same (see Unpublished Japanese Patent Application No. 2006-263562); and high c-axis orientation, high specific surface area ZnO crystal self-supported films and methods of manufacture thereof (see Unpublished Japanese Patent Application No. 2007-001141).

In such prior art, ZnO particles are manufactured by, for example, adding ammonia (28% aqueous solution) to a 50° C. aqueous solution of zinc acetate and holding the solution at 50° C. while stirring. The concentrations of zinc acetate and ammonia in the solution are respectively 15 mM (zinc acetate) and 30, 60 or 90 mM (ammonia), with the molar ratio therebetween ([NH₃]/[Zn]) being adjusted to 2.0, 4.0 or 6.0.

The pH under these three sets of conditions was respectively 7.04, 7.50 and 8.93. In addition, the synthesis of whisker-like particles of ZnO and ZnO shape control have been reported. However, the literature contains no reports on the immobilization of ZnO whiskers on FTO substrate and the formation of oriented ZnO whisker films by aqueous solution processes.

### SUMMARY OF THE INVENTION

In light of these circumstances and the above-indicated prior art, the inventors have conducted repeated and intensive investigations with the express intention of developing a whisker film-forming method that can be used to form ZnO whisker films having a high specific surface area and a high conductivity, and of developing such ZnO whisker film products. As a result, the inventors have discovered that it is possible by using a solution process to produce a ZnO whisker film that is a nanostructure endowed with both a high specific surface area and a high electrical conductivity. It is therefore an object of the present invention to provide a ZnO whisker film produced by a solution process, which film is a nanostructure having both a high specific surface area and a high electrical conductivity. Another object of the invention is to provide a method of manufacturing such a film.

In order to solve the above problems, the present invention comprises the following technical means.
(1) A ZnO whisker film characterized by that the film is formed on a substrate, the film comprises primarily (at least 50 mol %) of ZnO crystals, the film is composed of accumulated whisker-like particles having an aspect ratio of more than 2, the film has a nanostructure endowed with both a high specific surface area and a high electrical conductivity.
(2) The ZnO whisker film according to (1) above, wherein the film is formed on a ZnO seed layer.
(3) The ZnO whisker film according to (1) above, wherein the whisker-like particles are particles in the shape of whiskers, needles, bars or rods.
(4) The ZnO whisker film according to (1) above, wherein the substrate is an FTO, glass, silicon, metal, ceramic or polymer substrate.
(5) The ZnO whisker film according to (1) above, wherein the substrate is in the form of a plate, particles, fibers or has a complex shape.
(6) A method of manufacturing a ZnO whisker film, comprising the step of adjusting one or more solution condition selected from starting material concentration, temperature and pH so as to induce the deposition of ZnO crystals, in a reaction solution system for depositing zinc oxide, and forming thereby a ZnO whisker film on a substrate.
(7) The method of manufacturing a ZnO whisker film according to (6) above, wherein the reaction solution system includes hexamethylenetetramine, ethylenediamine or ammonia, and/or, polyethyleneimine, amino group-bearing polymer or amino group-bearing monomer.
(8) The method of manufacturing a ZnO whisker film according to (6) above, wherein the ZnO whiskers are caused to grow perpendicular or non-perpendicular to the substrate by using a smooth substrate or a textured substrate.
(9) The method of manufacturing a ZnO whisker film according to (6) above, wherein a ZnO crystal seed layer is formed on the substrate, and a ZnO whisker film is formed on the ZnO seed layer.
(10) The method of manufacturing a ZnO whisker film according to (6) or (9) above, wherein the number of whiskers per unit surface area of the substrate is controlled by adjusting a solution condition in the reaction solution system or by adjusting a degree of densification of the seed layer.
(11) An electronic device material characterized by comprising the ZnO whisker film defined in any one of (1) to (5), the ZnO whisker film being a nanostructure having both a high specific surface area and a high electrical conductivity.
(12) An electronic device characterized by comprising the electronic device material defined in (11) above, wherein the electronic device is a molecular sensor, a gas sensor, a solution sensor or a dye-sensitized solar cell.

### BRIEF DESCRIPTION OF THE DRAWINGS

FIG. 1 shows x-ray diffraction (XRD) patterns for ZnO whisker films formed on FTO substrate: (a) ZnO deposited directly on FTO substrate; and (b) ZnO whisker film produced on a ZnO seed layer formed on FTO substrate;

FIG. 2A shows an FE-SEM image of an FTO substrate, and FIG. 2B shows an FE-SEM image of a ZnO seed layer formed on an FTO substrate;

FIG. 3A shows an FE-SEM image of a ZnO whisker film, and FIGS. 3B and 3C show enlarged images thereof;

FIGS. 4A to 4C show FE-SEM images of: a cross sectional image of a ZnO whisker film (ZnO seed layer formed by dip-coating in a 0.025 M solution); a tilted image of a ZnO whisker film (ZnO seed layer formed by dip-coating in a 0.025 M solution); and a cross-sectional image of a ZnO whisker film (ZnO seed layer formed by dip-coating in a 0.1 M solution), respectively; and

FIG. 5 shows high-resolution TEM images and an electron beam diffraction pattern of a ZnO whisker.

### DESCRIPTION OF THE PREFERRED EMBODIMENTS

The invention is described more fully below.

The object of the present invention, which was arrived in light of the foregoing, was to provide a ZnO whisker film and a method of manufacturing such film. The method of the invention grows ZnO crystals anisotropically in the shape of whiskers from ZnO seeds so as to form a ZnO whisker film in which the ZnO whiskers are oriented in a direction perpendicular to the substrate.

In the present invention, the ZnO whisker film is a nanostructure in which a high specific surface area, a high electrical conductivity and interwhisker spacing controllability can all be achieved. It is anticipated that such ZnO whisker films will be capable of achieving high performance characteristics as electronic devices for molecular sensors, gas sensors, solution sensors and dye-sensitized solar cells.

Moreover, the present invention, because it achieves the formation of a ZnO whisker film using an aqueous solution process, has a number of advantages, such as the ability to form ZnO whisker films on low thermal resistance substrates and solid surfaces of complex shape, the fact that it is a low-temperature, low-energy consumption process, and the ability to synthesize ZnO whisker films in an open system type of apparatus.

In one aspect, the present invention is characterized by being a ZnO whisker film formed on a substrate and composed primarily (at least 50 mol %) of ZnO crystals, which film is formed by the accumulation of whisker-like particles having an aspect ratio of 2 or more and is a nanostructure endowed with both a high specific surface area and a high electrical conductivity.

In another aspect, the present invention is characterized by being a method of manufacturing the above-described ZnO whisker film, which method includes the step of adjusting, in a reaction solution system for depositing zinc oxide, one or more solution condition selected from the starting material concentration, temperature and pH so as to induce the deposition of ZnO crystals and thereby form a ZnO whisker film on a substrate.

In the present invention, preferred modes of working the present invention are that of including, within the reaction solution system, hexamethylenetetramine, ethylenediamine or ammonia, and/or polyethyleneimine, amino group-bearing polymer or amino group-bearing monomer; that of creating a ZnO crystal seed layer on the substrate, and subsequently forming a ZnO whisker film on the ZnO seed layer; and that of controlling the number of whiskers per unit surface area of the substrate by adjusting solution condition in the reaction solution system or by adjusting the degree of densification of the seed layer.

The most important feature of the present invention is the use of a ZnO seed layer and anisotropic growth of ZnO crystals to synthesize a ZnO whisker film within an aqueous solution. In the zinc-containing solution for seed layer formation, aside from the zinc acetate solution in the subsequently described working example, use may also be made of other zinc-containing solutions such as a zinc nitrate solution.

Alternatively, various types of aqueous solutions may be used, provided they are zinc-containing solutions.

Any process which is capable of depositing zinc or a substance containing zinc ions on the surface of a substrate may be used, including not only treatment involving the application of a solution, but even such treatment as spraying a zinc nitrate powder onto the substrate surface. Methods of coating with a solution include not only dip coating and spin coating, but also any other process capable of applying the solution to the substrate surface, such as a drawing method or a spraying method.

In the practice of the invention, heat treatment (about 350° C.) of the zinc-containing solution is used to carry out crystallization under heating conditions that allow crystallization to occur. Not only is it possible to modify such conditions as the temperature, atmosphere and treatment time, so long as the treatment brings about crystallization, use may even be made of light treatment and solution treatment. In addition to formation of a ZnO seed layer by heating a zinc-containing solution, ZnO crystal deposition treatment from an aqueous solution may be used, provided it is treatment that enables zinc crystals to be applied onto the substrate. As used herein, “ZnO seed layer” refers to a layer which promotes the formation of ZnO whiskers.

Instead of a crystallized ZnO seed layer, it is possible to use amorphous ZnO, a zinc-containing substance such as zinc acetate, or a mixture thereof. Use may even be made of a single-crystal ZnO layer instead of the crystallized ZnO seed layer. That is, it is possible, by using a single-crystal ZnO layer or the like instead of a crystallized ZnO seed layer, to cause the ZnO whiskers to be tilted or oriented in the same direction.

It is also possible to use another seed layer which does not contain zinc in place of the crystallized ZnO seed layer. Depending on the solution conditions, use may be made of a hydrophobic surface or a hydrophilic surface instead of the crystallized ZnO seed layer. Depending on the solution conditions, yet another possibility is to not use a seed layer.

Aside from an FTO substrate, substrates made of various other material may be used, such as glass, silicon, metal, ceramic or polymer substrates. Aside from plate-like substrates, use may also be made of particulate substrates, fibrous substrates and substrates of complex shape. The zinc-containing aqueous solution used to form the ZnO whisker film is not limited only to the zinc acetate solution mentioned in the subsequently described example; use may be made of zinc acetate solutions or other zinc-containing aqueous solutions.

Alternatively, so long as the reaction system is capable of depositing zinc oxide, a nonaqueous solution (e.g., organic solution) type reaction system may be used. Use may even be made of a hydrothermal reaction, provided the reaction system deposits zinc oxide. It is also possible to use ethylenediamine or ammonia instead of the hexamethylenetetramine included in the reaction solution system.

Instead of adding hexamethylenetetramine or the like, it is also possible to induce the deposition of ZnO crystals by altering the temperature, starting material concentration or pH. An organic molecule such as an amino group-bearing polymer or monomer may be used in place of polyethyleneimine. Similarly, instead of adding polyethyleneimine or the like, it is possible to induce the deposition of ZnO crystals by altering the temperature, starting material concentration or pH.

The temperature may be used, in combination with the starting material concentration, additives, pH and other factors, within a range of from the solidification point to the boiling point of the aqueous solution (from about 0° C. to about 99° C.). When producing a ZnO whisker film, aside from an FTO substrate, it is possible to use various other types of substrates, such as glass, silicon, metal, ceramic and polymer substrates. Moreover, aside from a plate-like substrate, it is possible to use granular substrates, fibrous substrates or substrates of complex shape.

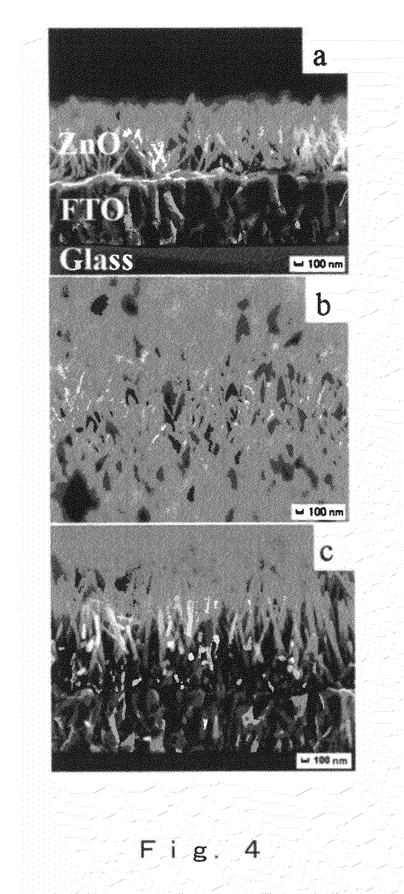

As can be seen in FIG. 4C, a layer such as a dense layer can be formed below the ZnO whiskers. This layer enhances the mechanical strength. As can be seen in FIG. 4A, it is also possible to not form a layer such as a dense layer below the ZnO whiskers. In the absence of a dense layer, continuous pores can be formed to the bottom of the ZnO whiskers.

By using a smooth substrate, ZnO whiskers can be grown perpendicular to the substrate. Alternatively, by using a textured substrate, ZnO whiskers can be grown non-perpendicular to the substrate. It is possible in this way to increase the open pores within the whisker film. By adjusting the surface shape of the substrate, a mixture of whiskers perpendicular to the substrate and whiskers non-perpendicular to the substrate may be grown.

The number of whiskers per unit surface area of the substrate can be increased by, for example, adjusting the solution conditions and densification of the seed layer. In FIG. 4B, the number of whiskers is 100 whiskers/μ². By adjusting the solution conditions, densifying the seed layer and the like, it is possible to achieve a continuous, dense film rather than a whisker film.

It is possible to make the whisker film a sparse film or even to form a single whisker alone by a technique such as adjusting the solution conditions or sparsely arranging the ZnO seeds on the substrate. The density in the number of the whiskers is 100 whiskers/μm² in FIG. 4B. By adjusting the solution conditions, or by densifying the seed layer or sparsely arranging the seeds, the density in the number of the whiskers may be controlled within a range of from 1 to 1,000 whiskers/μm².

It is also possible to form a continuous whisker body or a continuous film in which the density in the number of whiskers is difficult to measure, or to form a porous film or dense film. By adjusting the solution conditions, etc., solids of various shapes, such as multi-needle whiskers, helical particles and radial particles, can be induced to deposit.

A typical method of manufacturing the ZnO whisker film of the invention is one in which a zinc acetate solution is spin-coated or added in a dropwise manner onto an FTO substrate to form a ZnO seed layer, after which washing with anhydrous ethanol and 10 minutes of air drying at 60° C. are carried out. When coating is carried out by dropwise addition, the coating process is repeated four times. Atmospheric heating is then carried out at, for example, 350° C. for 20 minutes, thereby forming a seed layer of ZnO crystals.

The ZnO whisker film is formed by preparing a mixed aqueous solution of zinc nitrate, hexamethylenetetramine and polyethyleneimine, vertically immersing therein the FTO substrate on which a ZnO seed layer has been formed, and holding the substrate in the immerse state for 2 hours while heating at, e.g., 88° C.. In this way, a ZnO whisker film is formed on the ZnO seed layer. The whisker film, because it is a nanostructure which can achieve both a high specific surface area and a high electrical conductivity, is capable of exhibiting high performance characteristics in electronic devices such as molecular sensors, gas sensors, solution sensors and dye-sensitized solar cells.

The present invention thus achieves the following effects.
(1) By forming a ZnO seed layer in a liquid-phase process and employing the anisotropic growth of ZnO crystals, a ZnO whisker film can be synthesized in a reaction solution.
(2) Because a vapor-phase process is not used, a ZnO whisker film can be manufactured on a solid surface which is planar or of complex shape with a simple apparatus and at low cost.
(3) A ZnO whisker film can be obtained without passing through hydrothermal treatment or treatment involving ZnO crystallization at a high temperature for an extended period of time.
(4) The whisker film of the invention, being a nanostructure which is capable of achieving a high specific surface area, a high electrical conductivity and a high interwhisker spacing controllability, is useful as a film capable of exhibiting high performance characteristics as electronic devices for molecular sensors, gas sensors, solution sensors and dye-sensitized solar cells.
(5) It is also useful in, for example, fluorescence devices, piezoelectric devices, thermoluminescent devices, devices which utilize high thermal conductivity (e.g., heat sinks), and thermoelectric materials.

The present invention is described in detail in the following example, which is illustrative and should not be construed as limiting the invention.

### EXAMPLE

In the example described below, a ZnO whisker film was manufactured by using a ZnO seed layer.

### (1) Method of Manufacturing ZnO Seed Layer

Zinc acetate (zinc acetate dihydrate (Zn(CH₃COO)₂.2H₂O, 99%)) was dissolved in anhydrous ethanol. The zinc acetate concentration was 0.01 M (mol/L).

The zinc acetate solution was spin-coated or dip-coated onto a washed FTO substrate, then washed with anhydrous ethanol and air-dried at 60° C. for 10 minutes. When dip-coating was used, this coating process was repeated four times. Next, atmospheric heating was carried out at 350° C. for 20 minutes, thereby forming a ZnO crystal seed layer.

### (2) Method of Manufacturing ZnO Whisker Film

First, 200 ml of a mixed aqueous solution of 0.025 M zinc nitrate (zinc nitrate hexahydrate (Zn(NO₃)₂.6H₂O, 99%), 0.025 M hexamethylenetetramine (HMT, C₆H₁₂N₄, 99%) and 0.005 M polyethyleneimine (PEI, (C₂H₅N)ₙ, branched mean molecular weight of 600, 99%) was prepared.

A beaker containing the reaction solution was placed in a 84° C. oil bath, and held at 84° C. for 30 minutes. Next, the FTO substrate on which a ZnO seed layer had been formed was vertically immersed in the solution and held that way without stirring. The substrate was held in this manner for 2 hours while the reaction solution was heated at 88° C. During the heating operation, the clear aqueous solution gradually became cloudy.

To verify the effects of the ZnO seed layer, an FTO substrate on which a ZnO seed layer had not been formed was heat-treated at 350° C., and similarly immersed in an aqueous solution of zinc nitrate. Following immersion, the substrate was repeatedly rinsed with deionized water and ethanol, then air dried at room temperature.

The crystal structure was evaluated by XRD (RINT-2100V manufactured by Rigaku Corp.). The crystal morphology and microstructure were examined with a field emission scanning electron microscope (FE-SEM) (JSM-6335FM manufactured by JEOL Ltd.).

### (3) Evaluation

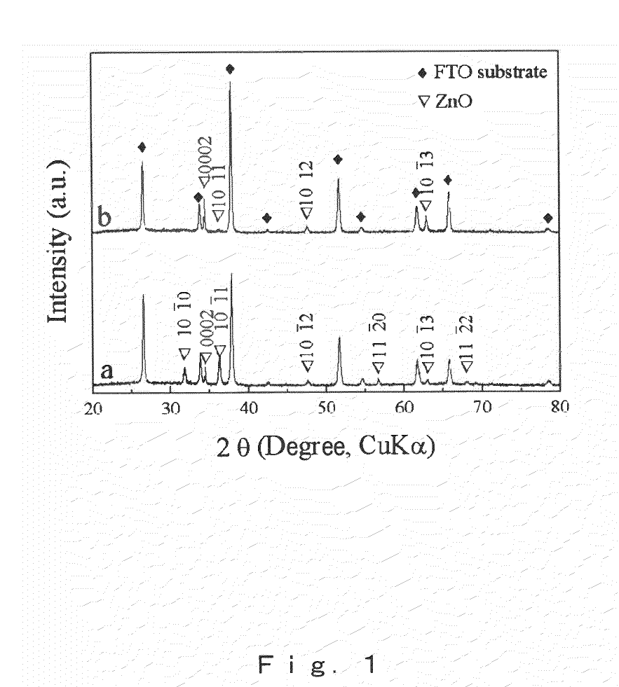

FIG. 1 shows XRD patterns for “ZnO deposited on an FTO substrate” in (a) and for a “ZnO whisker film produced on an FTO substrate on which a ZnO seed layer has been formed” in (b). Diffraction lines attributable to SnO₂ on the FTO substrate surface can be seen in each of the XRD patterns.

Peaks from each of the deposits were attributed to ZnO (JCPDS card (36-1451) for the typical wurtzite-type ZnO crystal (hexagonal, P6₃mc)). However, the relative intensities of the diffraction lines attributable to ZnO differed in each case.

In the ZnO deposited on the FTO substrate ((a) of FIG. 1), the diffraction line 10-11 has a greater intensity than 0002, and the line 10-10 has about the same intensity as 0002. However, in the ZnO whisker film produced on an FTO substrate on which a ZnO seed layer had first been formed ((b) of FIG. 1), very weak diffraction lines 10-10 and 10-11 and a strong diffraction line 0002 were observed.

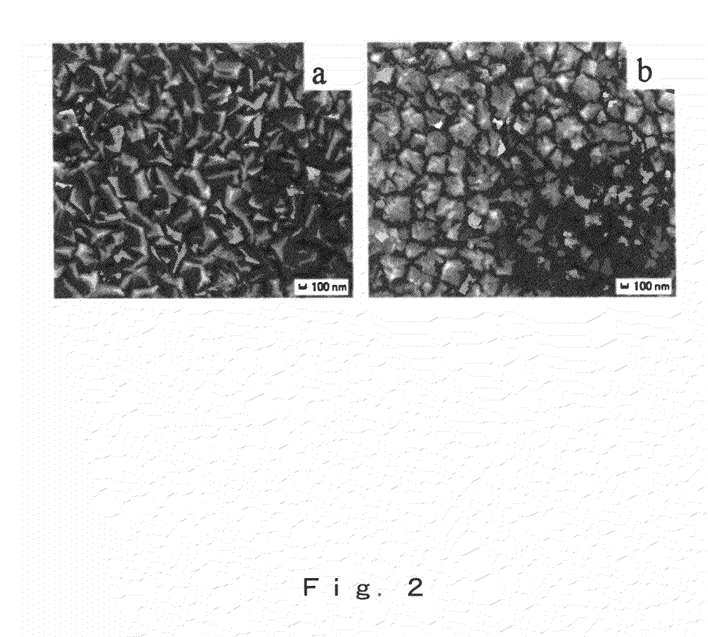

This indicates that, in the “ZnO whisker film produced on an FTO substrate on which a ZnO seed layer had been formed” ((b) of FIG. 1), the ZnO whiskers that grew in the c-axis direction are oriented and grow so as to stand upright in the perpendicular direction on the substrate. FIGS. 2A and 2B show FE-SEM images of the surface of an FTO substrate and of the surface of an FTO substrate following formation of a ZnO seed layer.

The surface of the untreated FTO substrate was covered with an SnO₂ layer having peaks and valleys ranging from several tens to several hundreds of nanometers in size. ZnO seed layer-forming treatment covered the surface with ZnO particles 20 nm or smaller in size so as to conform with the peaks and valleys.

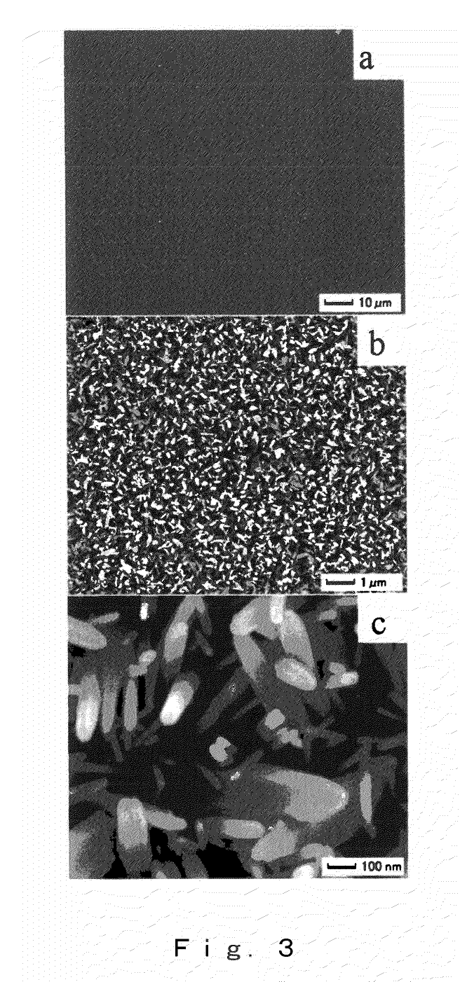

Because the amount of ZnO nanoparticles which form the seed layer is very small, ZnO diffraction lines were not observed on an XRD pattern of the FTO substrate following seed layer formation. FIGS. 3A to 3C show the SEM images of the seed layer-bearing FTO substrate taken following immersion of the substrate in the aqueous solution of zinc nitrate.

ZnO whiskers having a diameter of 30 to 150 nm grew in a direction perpendicular to the substrate, and densely covered the FTO surface (FIGS. 3A and 3B). The length of the whiskers (thickness of the whisker film) was uniform (FIGS. 3A and 3B). It is apparent from the enlarged image that the whiskers had a hexagonal cross-sectional shape (FIG. 3C).

This is due to the fact that ZnO has a hexagonal crystal structure and the ZnO which has formed is single-crystal ZnO. FIGS. 4A to 4C show cross-sectional and tilted images of the ZnO whisker film. The seed layer was formed by dip coating in FIGS. 4A and 4B, and by spin coating in FIG. 4C. In FIG. 4B, the number of whiskers (number density) per unit surface area of the substrate was 100 whiskers/μm².

It is apparent from the images that ZnO whiskers of uniform length have grown from the FTO surface, forming a dense whisker film. Moreover, many whiskers that have grown at an angle owing to the peaks and valleys on the surface of the FTO substrate can be seen. The length of the whiskers, as estimated from the cross-sectional SEM image, was about 900 nm.

By using spin coating instead of dip coating to carry out ZnO seed layer formation, ZnO whiskers of uniform diameter were successfully achieved (FIG. 4C; concentration, 0.1 M; 2 hours immersion). At a solution concentration of 0.025 M, whiskers having a diameter of 30 to 80 nm formed. At a concentration of 0.1 M, whiskers having a diameter of 0.9 to 1.5 μm formed.

In this way, it is possible to form a ZnO whisker film under a broad range of concentration conditions, and the size of the ZnO whiskers can be increased as the solution concentration is increased. Moreover, by using a ZnO seed layer, it is possible form a ZnO whisker film on various types of substrates, such as FTO, ITO, amorphous glass and silicon.

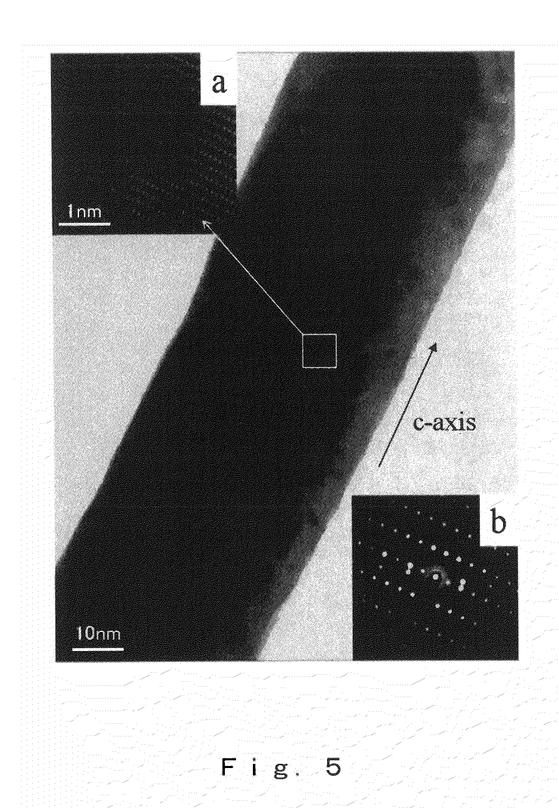

The high-resolution TEM images (FIG. 5, (a) in FIG. 5) and electron beam diffraction image ((b) in FIG. 5) show that the ZnO whiskers are single-crystal ZnO. These images also show that the whiskers undergo anisotropic growth in the c-axis direction ((0001) direction). The lattice spacing estimated from the TEM images was 0.26 nm, which agreed with the spacing of (0002) planes for ZnO ((a) in FIG. 5).

As is apparent from SEM observation, the ZnO whisker film had many nanosize open pores. The whiskers, as can be seen from the TEM images, were single-crystal ZnO which grew anisotropically in the c-axis direction.

These single-crystal ZnO whiskers were surrounded by nonpolar planes. In a ZnO powder, it has been reported that the nonpolar planes (−1010) exhibit a high CO gas adsorptivity (Reference: D. Scarano, G. Spoto, S. Bordiga, A. Zecchina and C. Lamberti: Surf. Sci. 276 (1-3), 281-298 (1992)).

It is conceivable from the foregoing that ZnO whiskers also have high adsorption characteristics. In addition, because ZnO whiskers are single crystals and grain boundaries do not exist in the whisker film region, an increase in electrical resistance due to grain boundaries is thus successfully avoided. Because ZnO whisker films have nanosize open pores, a high surface area, a high electrical conductivity and high adsorption properties, they are expected to provide excellent characteristics when used in dye-sensitized sensors or dye-sensitized solar cells.

### (4) Crystal Growth Mechanism

ZnO whiskers have a shape characterized by pointed tips and flat hexagonal planes which are connected together by six rectangles. Within the whisker film, as the distance from the substrate increases, the whisker shape gradually becomes more slender, approaching a needle-like shape.

Wurtzite ZnO crystals generally have a hexagonal crystal structure and are composed of six nonpolar (10-10) planes, a polar oxygen plane (000-1) and a polar zinc plane (0001). The polar planes, which have polarity at the surface, are thermodynamically less stable than the nonpolar planes. Hence, to lower the surface energy of the crystal, rearrangement is carried out, as a result of which the crystal growth rate tends to increase.

As is well known, crystal planes having a high crystal growth rate disappear more rapidly. The crystals thus exhibit a form covered with crystal planes having a slow growth rate.

The relative growth rates V of the various crystal planes under hydrothermal conditions are reported to be as follows.
V(0001) >V(-101-1) >V(−1010) >V (−1011) >V(000-1)
(Reference 1: H. Zhang, D. Yang, Y. J. Ji, X. F. Ma, J. X. and D. L. Que: J. Phys. Chem. B 108, 3955-3958 (2004);
Reference 2: R. A. Laudies and A. A. Ballman: J. Phys. Chem. 64, 688-691 (1960)).

Hence, the most stable crystal form is a hexagonal prism-like shape that is extended in the c-axis direction. PEI, which is used as an additive in the present reaction system, has many amino groups on a long molecular chain. These amino groups are believed to be selectively adsorbed onto specific crystal planes and to exert a large influence on the surface free energy and the crystal growth rate (Reference: V. C. Sousa, A. M. Segadaes, M. R. Morelli and R. Kiminami: J. Inorg. Mater. 1 (3-4), 235-241 (1999)). It is thus conceivable that, in the present reaction system as well, PEI is adsorbed at the nonpolar planes and suppresses crystal growth, thereby increasing the growth rate of the polar planes (0001) and (000-1).

Moreover, in the case of whisker growth on a ZnO seed layer, it is thought that the seed layer promotes heterogeneous nucleation, causing ZnO whisker formation to occur on the ZnO seeds, after which, because the polar planes in contact with the substrate cannot grow, anisotropic growth proceeds in a direction perpendicular to the substrate. This is apparently why the planes in contact with the ZnO seed layer exhibit a hexagonal shape, and the whisker tips that are the growing ends have pointed tips.

As described above, the present invention relates to a ZnO whisker film and a method of manufacture thereof. The invention makes it possible, by utilizing the growth of a ZnO seed layer in a liquid-phase process and the anisotropic growth of ZnO crystals, to synthesize a ZnO whisker film within a reaction aqueous solution. In this invention, because a vapor-phase process is not employed, a ZnO whisker film can be manufactured on a solid surface having a planar or complex shape using a simple apparatus and at a low cost. Moreover, a ZnO whisker film can be obtained without hydrothermal treatment or high-temperature, long-term ZnO crystallization treatment. The whisker film of the invention is a nanostructure which has a high specific surface area, a high electrical conductivity and good interwhisker spacing controllability, enabling it to exhibit good characteristics in electronic devices such as molecular sensors, gas sensors, solution sensors and sensitized-dye solar cells.

What is claimed is:

1. A ZnO whisker film characterized by that the film is formed on a substrate, the film comprises primarily (at least 50 mol %) of ZnO crystals, the film is composed of accumulated whisker-like particles having an aspect ratio of more than 2, the film has a nanostructure endowed with both a high specific surface area and a high electrical conductivity.

2. The ZnO whisker film of claim 1, wherein the film is formed on a ZnO seed layer.

3. The ZnO whisker film of claim 1, wherein the whisker-like particles are particles in the shape of whiskers, needles, bars or rods.

4. The ZnO whisker film of claim 1, wherein the substrate is an FTO, glass, silicon, metal, ceramic or polymer substrate.

5. The ZnO whisker film of claim 1, wherein the substrate is in the form of a plate, particles, fibers or has a complex shape.

6. A method of manufacturing a ZnO whisker film, comprising the step of adjusting one or more solution condition selected from starting material concentration, temperature and pH so as to induce the deposition of ZnO crystals, in a reaction solution system for depositing zinc oxide, and forming thereby a ZnO whisker film on a substrate.

7. The method of manufacturing a ZnO whisker film according to claim 6, wherein the reaction solution system includes hexamethylenetetramine, ethylenediamine or ammonia, and/or, polyethyleneimine, amino group-bearing polymer or amino group-bearing monomer.

8. The method of manufacturing a ZnO whisker film according to claim 6, wherein the ZnO whiskers are caused to grow perpendicular or non-perpendicular to the substrate by using a smooth substrate or a textured substrate.

9. The method of manufacturing a ZnO whisker film according to claim 6, wherein a ZnO crystal seed layer is formed on the substrate, and a ZnO whisker film is formed on the ZnO seed layer.

10. The method of manufacturing a ZnO whisker film according to claim 6 or 9, wherein the number of whiskers per unit surface area of the substrate is controlled by adjusting a solution condition in the reaction solution system or by adjusting a degree of densification of the seed layer.

11. An electronic device material characterized by comprising the ZnO whisker film defined in any one of claims 1 to 5, the ZnO whisker film being a nanostructure having both a high specific surface area and a high electrical conductivity.

12. An electronic device characterized by comprising the electronic device material defined in claim 11, wherein the electronic device is a molecular sensor, a gas sensor, a solution sensor or a dye-sensitized solar cell.
